(19) United States
(12) Patent Application Publication
(10) Pub. No.: US 2014/0216920 A1
(43) Pub. Date: Aug. 7, 2014

(54) Method of Producing Nanoparticles

(71) Applicants: David Thomas Britton, Cape Town (ZA); Manfred Rudolf Scriba, Pretoria (ZA)

(72) Inventors: David Thomas Britton, Cape Town (ZA); Manfred Rudolf Scriba, Pretoria (ZA)

(73) Assignee: PST Sensors (Proprietary) Limited, Cape Town (ZA)

(21) Appl. No.: 14/131,612

(22) PCT Filed: Jun. 15, 2012
(86) PCT No.: PCT/IB2012/053023

§ 371 Date: Mar. 31, 2014

(30) Foreign Application Priority Data
Jul. 8, 2011 (ZA) 2011/05035

(51) Int. Cl. B01J 19/08; C30B 7/14

(52) U.S. Cl. CPC B01J 19/088; C30B 7/14
USPC 204/164

(57) ABSTRACT

A method is provided of producing nanoparticles in the size range 1 nm to 1000 nm through the synthesis of one or more precursor fluids. The method includes providing a fluid medium comprising at least one precursor fluid and generating an electrical spark within said fluid medium to cause pyrolysis of said at least one precursor fluid in a relatively hot plasma zone to produce at least one radical species. Nanoparticles are formed by nucleation in the fluid medium in a cooler reaction zone about the plasma zone, where the radical species acts as a reactant or catalytic agent in the synthesis of material composing the nanoparticles. The spark is created by an electrical discharge having a frequency between 0.01 Hz and 1 kHz, and a total energy between 0.01 J and 10 J. The nanoparticles may comprise silicon, or compounds or alloys of silicon, and are typically useful in electronic and electrical applications.

### BACKGROUND OF THE INVENTION

THIS invention relates to a process for the production of nanoparticles by chemical vapour synthesis (CVS) involving the pyrolysis of at least one molecular precursor species.

The CVS method of particle production is based on the pyrolysis of at least one precursor gas. For the purposes of this specification pyrolysis refers to the thermally assisted cracking of molecules, although other kinematic collision processes may occur, into radicals such as atoms and ions. Chemical vapour synthesis refers to the complete process of assembling larger units such as molecules, atomic clusters, nanoparticles and even micron scale particles from the reactive species produced during the pyrolysis, or through their interaction with the molecules of the unreacted gas. This interaction may be a direct chemical reaction or the promotion of a chemical reaction through catalytic activity.

In these processes the inclusion of low concentrations of additional gases may result in the inclusion of dopant atoms in the nanoparticles or the formation of alloys. Processes that are known to practitioners skilled in the art of nanoparticle production from the vapour phase include laser pyrolysis, hot wall reactor synthesis and plasma pyrolysis. Nanoparticles produced by such methods are of industrial significance for their applications as phosphors, in printed electronics, in tribology, magnetic and electrorheological fluids, and in nanocomposite materials, as well as finding a wide use in advanced scientific research.

### SUMMARY OF THE INVENTION

According to the invention there is provided a method of producing nanoparticles through the synthesis of one or more precursor fluids, wherein at least one such precursor undergoes pyrolysis, or cracking, initiated by an electrical spark, to produce one or more radical species. The radical species acts as a reactant or catalytic agent in the synthesis of the material composing the nanoparticle which forms by nucleation in the fluid medium. In a preferred embodiment the fluids compose a low pressure gaseous environment, but such a spark may also be caused to occur in an insulating liquid. In the latter case, the liquid itself may form a precursor material or it may comprise a solution containing the precursor materials. Alternatively, in a gaseous environment, liquid or solid precursor materials may be introduced into the region of the spark as an aerosol of particles or droplets in a stream of a carrier gas. This carrier gas may itself comprise a precursor material or may be inert, and not participate in any chemical processes. Similarly, an inert gas may be added to the precursor gases as a dilutant.

More specifically, according to the invention there is provided a method of producing nanoparticles in the size range 1 nm to 1000 nm through the synthesis of one or more precursor fluids, the method including providing a fluid medium comprising at least one precursor fluid and generating an electrical spark within said fluid medium to cause pyrolysis of said at least one precursor fluid in a relatively hot plasma zone to produce at least one radical species, and to form nanoparticles by nucleation in the fluid medium in a cooler reaction zone about the plasma zone, wherein said at least one radical species acts as a reactant or catalytic agent in the synthesis of material composing said nanoparticles.

The electrical discharge forming the spark may have a frequency between 0.01 Hz and 1 kHz, and preferably between 1 Hz and 100 Hz.

The spark may have a total energy between 0.01 J and 10 J and preferably between 0.1 and 1 J.

The precursor materials may all be in gaseous form.

Alternatively, at least one of the precursor materials may be in liquid form, the said liquid being either a pure non-conducting liquid or a non-conducting solution of other materials in an appropriate solvent.

Further alternatively, at least one of the precursor materials may ordinarily be a solid or liquid and be introduced into the spark as an aerosol composed of particles or droplets in a carrier gas.

In a preferred embodiment of the method, rapid condensation of the nanoparticles away from the region of the spark results in the formation of spherical nanoparticles.

The spherical nanoparticles may be single crystalline. The nanoparticles may form compact spherical or ellipsoidal clusters. The nanoparticles may be agglomerated to form chains, a branched cluster, or a network.

The nanoparticles may nucleate around a pre-existing nanoparticle to produce a binary nanoparticle with a core-shell structure.

In particular, the nanoparticles may be nucleated around pre-existing nanoparticles injected into cooler regions of the medium surrounding the spark to form binary nanoparticles with a core-shell structure.

Different precursor materials may be introduced at different distances from the spark allowing the nucleation of heterogeneous particles with either a composition gradient or a core-shell structure, which may comprise multiple shells.

The nanoparticles may comprise silicon.

The nanoparticles may comprise a compound of silicon, including silica, silicon carbide, or silicon nitride.

The nanoparticles may comprise an alloy of silicon including silicon doped with boron, phosphorous or arsenic, and also silicon-carbon and silicon-germanium alloys.

The nanoparticles may comprise a polymer.

The nanoparticles produced by the method of the invention comprise inorganic semiconductor materials, and have non-insulating surfaces for use in electronic and electrical applications in general, and specifically in those applications where semiconducting properties are required.

### BRIEF DESCRIPTION OF THE DRAWINGS

FIG. 1 is a schematic diagram showing the production of nanoparticles formed by using an electric spark generated between two electrodes in the reaction chamber of FIG. 1;

FIG. 2 is a transmission electron microscope (TEM) image obtained from silicon nanoparticles produced according to the method of the invention;

FIG. 3 is a histogram of the size distribution of silicon nanoparticles produced according to the method of the invention.

FIG. 4 is a high magnification TEM image of a silicon nanoparticle produced according to the method of the invention;

FIG. 5 is a graph of the resistivity of compressed silicon nanopowder produced by the method of the invention; and

### DESCRIPTION OF PREFERRED EMBODIMENTS

In this invention, an electric discharge or spark is used to perform the pyrolysis of one or more precursor gases, specifically for the production of stable nanoparticles by chemical vapour synthesis, involving the pyrolysis of at least one molecular precursor species and the nucleation of the nanoparticles in the surrounding gaseous environment. It particularly concerns the synthesis of nanoparticles of inorganic semiconductor materials, with non-insulating surfaces for use in electronic and electrical applications in general, and specifically in those applications where semiconducting properties are required.

Early well-known experiments investigated the use of a high energy spark to promote the synthesis of complex organic molecules from simple precursor gases. Specifically, compounds such as amino acids were produced from the mixture of gases, including methane, oxygen and ammonia, expected in the atmosphere of the young earth. The spark pyrolysis method relies on the dissociation or cracking of the precursor gases by the electrical excitation of the electrons and ions in the spark plasma. The process has similarities to the method of pulsed laser pyrolysis, which has short heating and rapid cooling cycles, but differs significantly in both the method of excitation and the spatial extent of the plasma and the associated temperature profile in the surrounding gas. Similarly the method described here has superficial similarities to plasma enhanced chemical vapour synthesis, as described in WO 2010/027959, U.S. 2006/0051505, and U.S. 2006/269690, which uses a radio frequency coupling of the electrical excitation, but which effectively excites the whole gaseous atmosphere.

A similar method to that described here, which does not involve the crucial pyrolysis step, is the well-known production of nanoparticles by a continuous arc between two separated electrodes, as described in WO 2003/022739 or JP 2010/095422, of which at least one is made of the material which composes the nanoparticles. Material from one or both electrodes is evaporated into the arc plasma, leading to the formation of nanoparticles through nucleation in the surrounding medium. Known modifications to this method include evaporating the electrode material into a reactive environment, such as air or oxygen, to produce oxide nanoparticles.

FIG. 1 shows, schematically, the processes occurring during the chemical vapour synthesis. When an arc discharge is generated between two electrodes (1), radical species (2) are produced by pyrolysis of one or more precursors in the relatively hot plasma core of the spark (3). One or more of the resulting radical species undergo interactions in a cooler reaction region (4) surrounding the plasma core of the spark to form the species (5) which comprise the desired nanoparticle. The interactions between the radical species, or between the radical and unreacted species, may simply form a route to chemical synthesis, or at least one such radical may act a as a catalytic agent which promotes a reaction between any of the other species present. More particularly such a catalytic reaction should involve one or more uncracked precursor species.

Local supersaturation of the final product results in nucleation and growth of nanoparticles (6) in the surrounding medium. The size, morphology and internal structure of the particles is thus primarily controlled by five factors: the pressure and temperature of the surrounding medium, and the length, energy and duration of the spark. Nanoparticles can be produced in the size range 1 nm to 1000 nm, but are preferably in the range 5 nm to 200 nm, and more preferably in the range 20 nm to 70 nm.

In this invention, a plasma with a small spatial extent is formed in the spark. Thus the cracking processes are similar to those occurring in plasma enhanced chemical vapour synthesis in that other kinematic collision processes may play a role in the cracking of the precursor molecules to form the radical species. Another superficial similarity with plasma enhanced chemical vapour synthesis is the electrical excitation of the plasma, which differs in the present invention in that it is directly coupled and only excites a limited region of the medium directly between the two electrodes and not the whole gaseous atmosphere as in methods employing radiofrequency coupling used in the prior art.

In the present invention therefore, the fluid medium contains cooler regions than in plasma enhanced chemical vapour synthesis, so that particles may form and cool at a faster rate thus limiting the growth and the re-arrangement of the atoms or, molecules constituting the particle. The method therefore is better suited to the production of small spherical particles, which may be amorphous, polycrystalline or single crystalline. Through control of the physical parameters of the surrounding material, for example for gas phase synthesis the flow rate, pressure, chamber temperature and the presence of quenching or dilution gases, the crystallinity can be controlled and spherical single crystal particles in the desired size range can be obtained.

Unlike in the plasma enhanced chemical vapour phase synthesis, in the method disclosed here the spark and associated plasma are short-lived, and so the temporal profile of the plasma bears some similarity to that found in pulsed laser pyrolysis, which has short heating and longer cooling cycles. However, the present method differs significantly not only in the method of excitation, but also the spatial extent of the plasma, and hence the temperature profile in the surrounding medium. More particularly, in the present invention the spark does not significantly heat the surrounding medium.

Variation of the temperature and pressure in the surrounding medium can be used to change the nucleation and condensation rates of the particles allowing the formation of larger structures. In particular, particles may be fused in situ to form compact spherical or ellipsoidal clusters, chains, branched clusters or complex dendritic networks. At elevated temperatures, if the nanoparticles are allowed to impinge on a substrate the method may be suitable for the deposition of compact layers and coatings.

The invention can be used to produce nanoparticles of most materials whose precursors may be introduced to the spark in the gas or liquid phase or as an aerosol. In the aerosol the carrier gas may be either inert or be composed of one of the precursor materials. The invention thus includes the fabrication of nanoparticles of all materials known to be deposited as thin films in chemical vapour deposition (CVD) processes, such as semiconductors, metals and ceramics. In an analogous manner to most known chemical vapour deposition processes, doping and alloying can be accomplished by mixing the precursor and dopants prior to feeding the mixture into the chamber, or by injecting them separately into the region of the spark. Similarly, inclusion of other phases, for example for the production of a binary particle with a core shell structure, may be achieved by injection of an aerosol into the nucleation region surrounding the spark.

The methods disclosed are particularly suited to the production of nanoparticles comprised of: silicon; its compounds such as silica, silicon nitride and silicon carbide; and its alloys including, inter alia, boron doped and phosphorous doped silicon, as well as silicon-carbon and silicon-germanium alloys.

Polymer and other organic nanoparticles, as well as carbon phases such as nanotubes and buckminster-fullerene molecules, may be produced by using the spark to pyrolise the precursor of a catalytic radical in a process similar to that occurring at the hot filament in initiated chemical vapour deposition as described by Gleeson et al in WO2007145657. Of particular relevance are fluorocarbons, as disclosed in WO9742356, and polyglycidylmethacrylate (PGMA), which may be nucleated around a core of a pre-existing metallic or ceramic nanoparticle as disclosed above.

In a preferred embodiment of the invention a spark is produced in a gaseous environment inside a reaction chamber by the application of a high electric potential between two electrodes. The reaction chamber may vary in size and may be constructed from stainless steel or glass or any other suitable material and is sealed to atmosphere by O-rings or the like, preventing the ingress of air into the chamber. The reaction chamber is filled with precursor gases which are introduced into the reaction chamber, and whose flow rate and pressure may be regulated. According to the invention the morphology, structure, crystallinity and size of the nanoparticles produced by the spark pyrolysis can be affected by the variation of the spark gap distance, energy of the spark, the pressure inside the reaction chamber, the flow rate and composition of the precursor gases.

The electrodes may constitute any conductive material, but a refractory metal with a high melting point and resistance to corrosion is preferred. From experience tungsten wire has proved to be an excellent electrode material. A spark will be produced only if the conditions for the ionisation of the gas in the chamber are satisfied. The conditions are determined by the pressure, voltage and spark distance. For a fixed spark gap the potential over the spark gap will thus have to be high enough to initiate the spark at a particular pressure. The spark location inside the chamber as well as the chamber size may also be varied to affect the particle size and agglomeration of the nanoparticles. The nucleation rate of nanoparticles may further be regulated by controlling the temperature of the chamber by either cooling or heating.

The precursor gas or gases may be introduced into the reaction chamber through a single inlet or through multiple inlets at the same or different locations on the chamber, allowing spatially varying distribution of precursors and reactive species. As an example, one or more gases may be distributed radially inside the chamber, facilitating the growth of nanoparticles with a gradient in their composition or a core-shell structure, with the possibility of multiple shells, as different species nucleate at different distances from the spark.

Example: Production of Doped Silicon Nanoparticles

To illustrate the method of the invention more fully, the production of p-type silicon nanoparticles is used as one example. The precursor gas was pure monosilane (SiH₄) diluted with 0.1% by volume of diborane (B₂H₆), which was delivered to the reaction chamber at a flow rate of 50 sccm and maintained at a pressure of 80 mbar. The level of doping in the resulting nanoparticles can be controlled by varying the concentration of diborane from approximately 1 part per million to in excess of 10% by volume. Any other known dopants can be added to the nanoparticles by the inclusion of their respective known precursors. As a particular example, n-type doping with phosphorous is achieved by the addition of phosphine or diphosphine, and with arsenic by the addition of arsine.

Other known silicon precursors such as disilane, and halogenated silanes such as the chlorosilanes or fluorosilanes, may be used. An inert dilutant gas such as argon or helium, may be used. Dilution of the precursor gas with hydrogen, as is well known in the chemical vapour deposition of silicon films, will also result in the production of nanoparticles, but is not recommended for the attainment of a stable surface. Particles comprising oxides, nitrides and oxynitrides, or with a surface layer comprised of such materials, can be produced by using one of either or both of oxygen and nitrogen as the dilutant gases, respectively.

Similarly, particles comprising alloys or compounds of silicon with other elements can be synthesised by including the precursors known to practitioners of chemical vapour deposition for these materials. This list is extensive, and should not be restricted to the following examples. Carbon, to synthesise nanoparticles of silicon carbide or silicon-carbon alloys, may be included, for example, by the addition of methane, a short chain alkane such as ethane, propane or butane, or alkene such as ethane or propene, as a secondary precursor gas, or an aromatic compound or other higher hydrocarbon in nebulised form. Similarly nanoparticles comprising silicon-germanium alloys, or elemental germanium, can be produced by the addition, or replacement, of the silane with a corresponding germane.

The high voltage power supply used to generate the spark was left in free running mode, with a capacitor repeatedly charging and discharging across the spark gap. In this arrangement, the average frequency of the spark discharge and its energy depends on the breakdown voltage, which depends on the size of the spark gap and the pressure inside the reaction chamber. In the present example the spark frequency is 9.5 Hz and the spark energy in the region of 0.6 J.

In an alternative process, a modulated high voltage pulse, for example but not limited to a square, triangular, sinusoidal or half-wave rectified waveform, with a defined frequency less than 1 kHz, and ideally greater than 0.01 Hz, may be used. Most preferably the spark frequency should be between 1 Hz and 100 Hz, with a total energy per spark between 0.01 and 10 J, and most preferably in the range 0.1 to 1 J.

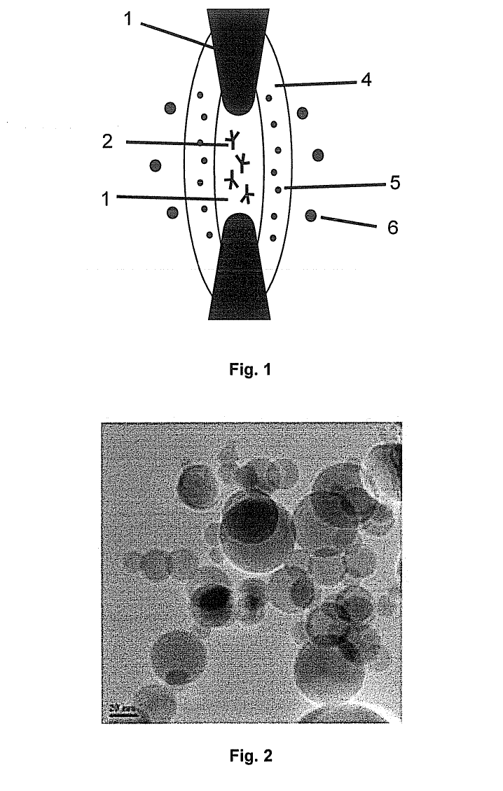

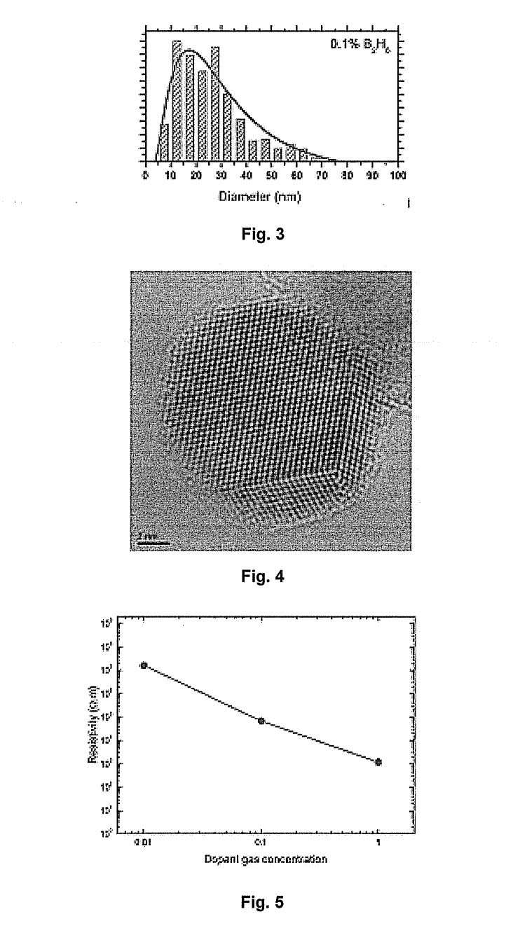

The silicon nanoparticles produced in accordance with the above described example of the invention are shown in the TEM image of FIG. 2. The silicon nanoparticles are spherical with a mean particle diameter between 20 and 40 nm as shown in the particle size distribution histogram of FIG. 3. The histograms represent intrinsic silicon nanoparticles produced at 40 mbar.

The silicon nanoparticles produced in accordance with the method of the invention, at 80 mbar with 0.1% diborane, are monocrystalline. This is revealed in the TEM images in FIG. 4, by the lattice structure visible over the full particle. It shows how the crystal structure extends fully, up to the outer atomic layer of the particle.

Both the size and the crystallinity of the nanoparticles, can be modified by control of the nucleation rate and temperature in the nucleation zone by varying the spark energy, pressure and flow rate of the gases in the reaction chamber. Rapid nucleation results in the formation of spherical particles, and at high pressure will lead to a polycrystalline or amorphous internal structure. At higher flow rates the particles will be smaller and less agglomerated. Control of the gas flow, and the reaction parameters, can therefore also allow synthesis of large structures comprising nanoparticles, such as compact spherical or ellipsoidal clusters, branched dendritic clusters, and large networks of particles.

Doping of the silicon nanoparticles with boron was confirmed by a reduction in resistivity with an increase in the concentration of the diborane precursor gas. The resistivity of the particles produced according to the method of the invention was measured by compressing a measured quantity of reference silicon nanopowder and the same quantity of nanopowder produced by the method of the invention, to the same density, between two conducting rods. The resistivity of the silicon nanoparticles produced in accordance with the invention, at 80 mbar with 0.01%, 0.1% and 1% diborane concentrations, is shown in FIG. 5. The decrease in resistivity with the increasing diborane concentration indicates an increase in doping concentration in silicon nanoparticles produced according to the invention.

1. A method of producing nanoparticles in the size range 1 nm to 1000 nm through the synthesis of one or more precursor fluids, the method including providing a fluid medium comprising at least one precursor fluid and generating an electrical spark within said fluid medium to cause pyrolysis of said at least one precursor fluid in a relatively short-lived hot plasma core of the spark which has a small spatial extent to produce at least one radical species, and to form nanoparticles by nucleation in the fluid medium In a cooler reaction zone surrounding the plasma core of the spark, wherein said at least one radical species acts as a reactant or catalytic agent in the synthesis of material composing said nanoparticles.

2. The method of claim 1 wherein the spark is created by an electrical discharge haying a frequency between 0.01 Hz and 1 kHz.

3. The method of claim 2 wherein the spark is created by an electrical discharge having a frequency between 1 Hz and 100 Hz.

4. The method of claim 1 wherein the spark has a total energy between 0.01 J and 10 J.

5. The method of claim 4 wherein the spark has a total energy between 0.1 and 1 J.

6. The method claim 1 wherein the precursor fluid comprises at least one precursor material in a gaseous form.

7. The method claim 1 wherein the precursor fluid comprises at least one precursor material in a liquid form, being either a pure non-conducting liquid or a non-conducting solution of other materials in an appropriate solvent,

8. The method of claim 1 wherein the precursor fluid comprises at least one precursor material which is ordinarily a solid or liquid and is introduced, into the spark as an aerosol composed of particles or droplets in a carrier gas.

9. The method of claim 1 wherein rapid condensation of the nanoparticles away from the region of the spark results in the formation of spherical nanoparticles.

10. The method of claim 9 wherein the spherical nanoparticles are single crystalline.

11. The method of claim 9 wherein the nanoparticles form compact spherical or ellipsoidal clusters,

12. The method of claim 1 wherein nanoparticles are agglomerated to form chains, a branched cluster, or a network.

13. The method of claim 1 wherein nanoparticles nucleate around pre-existing nanoparticles to produce binary nanoparticles with a core-shell structure.

14. The method of claim 13 wherein the nanoparticles nucleate around pre-existing nanoparticles injected into cooler regions of the medium surrounding the spark to form binary nanoparticles with a core-shell structure,

15. The method of claim 1 wherein different precursor materials are introduced at different distances from the spark allowing the nucleation of heterogeneous particles with either a composition gradient or a core-shell structure.

16. The method of claim 1 wherein the nanoparticles comprise silicon.

17. The method of claim 1 wherein the nanoparticles comprise a compound of silicon, including silica, silicon carbide, or silicon nitride.

18. The method of claim 1 wherein the nanoparticles comprise an alloy of silicon including silicon doped with boron, phosphorous or arsenic, and also silicon-carbon and silicon-germanium alloys.

19. The of claim 1 wherein the nanoparticles comprise a polymer.

20. The method of claim 1 wherein the nanoparticles comprise inorganic semiconductor materials and have non-insulating surfaces for use in electronic and electrical applications in general, and specifically in those applications where semiconducting properties are required.
